(19) United States
(12) Patent Application Publication
(10) Pub. No.: US 2023/0006426 A1
(43) Pub. Date: Jan. 5, 2023

(54) GROUP III-N LIGHT EMITTER ELECTRICALLY INJECTED BY HOT CARRIERS FROM AUGER RECOMBINATION

(71) Applicant: The Regents of the University of California, Oakland, CA (US)

(72) Inventors: Daniel A. Cohen, Santa Barbara, CA (US); Daniel Myers, Kirkland (US); Claude C. A. Weisbuch, Paris (FR); Steven P. DenBaars, Goleta, CA (US)

(73) Assignee: The Regents of the University of California, Oakland, CA (US)

(21) Appl. No.: 17/801,612

(22) PCT Filed: Feb. 17, 2021
(86) PCT No.: PCT/US21/18329

§ 371 Date: Aug. 23, 2022

Related U.S. Application Data
(60) Provisional application No. 62/983,028, filed on Feb. 28, 2020.

(51) Int. Cl. H01S 5/343; H01S 5/042; H01S 5/20; H01S 5/028

(52) U.S. Cl. CPC H01S 5/34333; H01S 5/04257; H01S 5/2031; H01S 5/028; H01S 5/0206

(57) ABSTRACT

A Group-III nitride light emitting device that utilizes scattering of hot carriers generated by Auger recombination from an externally electrically-driven, relatively narrow band gap carrier generation region into a relatively wide band gap carrier recombination region, such that the relatively wide band gap carrier recombination region of the Group-III nitride light emitting device is internally electrically injected by the hot carriers generated in the externally electrically-injected relatively narrow band gap carrier generation region. The device is used for generation of incoherent light (a light-emitting diode) or coherent light (a laser diode).

### CROSS REFERENCE TO RELATED APPLICATIONS

This application claims the benefit under 35 U.S.C. Section 119(e) of the following co-pending and commonly-assigned application:

U.S. Provisional Application Ser. No. 62/983,028, filed on Feb. 28, 2020, by Daniel A. Cohen, Daniel J. Myers, Claude C. A. Weisbuch and Steven P. DenBaars, entitled “GROUP-III NITRIDE LIGHT EMITTER ELECTRICALLY INJECTED BY HOT CARRIERS FROM AUGER RECOMBINATION,” attorneys' docket number G&C 30794.0758USP1 (UC 2020-094-1);

which application is incorporated by reference herein.

### BACKGROUND OF THE INVENTION

### 1. Field of the Invention

This invention relates to Group-III nitride light emitters electrically injected by hot carriers from Auger recombination.

### 2. Description of the Related Art

(Note: This application references a number of different publications as indicated throughout the specification by one or more reference numbers within brackets [ ]. A list of these different publications ordered according to these reference numbers can be found below in the section entitled “References.” Each of these publications is incorporated by reference herein.)

Lasers operating at ultraviolet (UV) wavelengths between 200-315 nm are useful for micromachining, lithography, microbial disinfection, (bio)chemical and environmental sensing, solar-blind and non-line-of-sight optical communication, and scientific instrumentation. These applications are currently served by excimer or ion gas lasers, dye or solid-state lasers photopumped by gas lasers, or by lasers using nonlinear optical methods to convert visible laser light to UV wavelengths. These existing UV laser systems are large, mechanically sensitive, and inefficient compared to diode injection lasers.

After decades of research, electrically injected diode lasers have been demonstrated at wavelengths as short as 272 nm, albeit only under pulsed operation at relatively high voltage and low efficiency [1]. The primary impediments to shorter wavelength operation is that the wide band gap AlGaN semiconductor layers needed for deep UV (DUV) operation cannot be effectively doped, resulting in very poor electrical contacts and excessive voltage and optical loss. The main impediments can be described in short by saying that it is difficult to electrically inject the wide band gap AlGaN semiconductor layers needed for deep UV (DUV) operation.

Indeed, when Mg doping was omitted from the AlN/AlGaN cladding and waveguide layers of DUV lasers of otherwise conventional design, and the structures were optically pumped by excimer lasers, laser oscillation was observed at wavelengths as low as 267 nm with reasonably low pump threshold fluences [2]. These experiments show that once carriers are introduced into the undoped wide band gap AlGaN or AlN layers, they may successfully diffuse to an active layer to produce laser gain.

One way to introduce carriers is through Auger effects. Vampola et al. [3] studied Auger-assisted carrier leakage from an electrically-driven InGaN quantum well into an adjacent AlGaN/GaN LED structure, observing visible light emission from a nearby monitor InGaN well. Binder et al. [4] and Nirschl et al. [5] also studied Auger scattering between nearby InGaN/GaN quantum wells. Iveland et al. [6] demonstrated surface emission of Auger scattered electrons from an electrically-driven InGaN quantum well LED, showing that such hot carriers may relax into a higher energy conduction band in GaN and transport to the surface as far as 200 nm away.

In all cases, the intent was to understand the role of Auger scattering in the efficiency droop of InGaN LEDs and no suggestion was made to intentionally use Auger scattering to pump UV emitters.

### SUMMARY OF THE INVENTION

To overcome the limitations in the prior art described above, and to overcome other limitations that will become apparent upon reading and understanding this specification, the present invention discloses a Group-III nitride light emitting device, based on carrier recombination in wide band gap semiconductor layers, that utilizes scattering of hot carriers internally generated by Auger recombination in an externally electrically-driven, relatively narrow band gap carrier generation region into a relatively wide band gap carrier recombination region, such that the relatively wide band gap carrier recombination region of the Group-III nitride light emitting device is internally electrically injected by the hot carriers generated in the externally electrically-driven relatively narrow band gap carrier generation region. The present invention therefore transforms the difficult task of electrical injection in a relatively wide band gap carrier recombination region into the much easier electrical injection in a relatively narrow band gap carrier generation region where hot carriers generated by Auger recombination will in turn excite the relatively wide band gap carrier recombination region.

A carrier reflecting structure may be incorporated into the device to redirect scattered hot carriers traveling away from an active region back toward an active region. A carrier anti-reflection structure may be incorporated into the device to increase transmission of the Auger scattered carriers toward an active region. Both the carrier reflecting and carrier anti-reflection structures may be made from one or more semiconductor layers or a semiconductor superlattice. For use in a laser, the carrier-reflecting and/or anti-reflection structures may be made with materials having a band gap and thickness such that the effective optical absorption edge is of higher energy than an intended operating photon energy.

### BRIEF DESCRIPTION OF THE DRAWINGS

FIG. 1A is a band diagram under bias of a c-plane embodiment of a laser diode according to the present invention, and FIG. 1B is a band diagram under bias of an m-plane embodiment of a laser diode according to the present invention.

FIG. 2 is a schematic view of an c-plane embodiment of the laser diode of FIG. 1A.

FIG. 3 is a schematic view of an m-plane embodiment of the laser diode of FIG. 1B, incorporating a Bragg reflector and antireflection superlattice to improve Auger injection into the laser diode's active region.

FIG. 4A is a schematic view of an alternative embodiment of the laser diode of FIG. 2, in which a second active region is incorporated, and which is designed to operate with a higher-order transverse optical mode.

FIG. 4B is a graph of depth vs. optical intensity for the device of FIG. 4A.

FIG. 5 is a flow chart showing the process steps for fabricating and operating a III-nitride based laser diode according to the present invention.

### DETAILED DESCRIPTION OF THE INVENTION

In the following description of the preferred embodiment, reference is made to the accompanying drawing which forms a part hereof, and in which is shown by way of illustration a specific embodiment in which the invention may be practiced. It is to be understood that other embodiments may be utilized, and structural changes may be made without departing from the scope of the present invention.

Overview

Practical diode lasers operating at wavelengths below 300 nm, e.g., ultraviolet wavelengths, have not yet been demonstrated, mainly because the required wide band gap of the semiconductor materials precludes formation of adequate electrical contacts. This invention describes the use of Auger scattering, usually thought of as an impediment to laser or LED performance, as a beneficial mechanism to electrically inject hot carriers into wide band gap materials without the need of direct electrical contact to those materials.

Specifically, the key innovation of the present invention is to introduce the carriers by Auger recombination from an adjacent lower band gap p-n junction that is electrically driven as in a visible diode laser. The result is an electrically driven single chip UV laser manufactured using standard microelectronic fabrication and packaging methods, without the need for critical alignment, mechanically robust and stable without precise temperature control, and with power and efficiency adequate for many portable applications.

Single chip diode lasers that operate at UV wavelengths offer many advantages over existing solid-state, ion and excimer, or frequency-doubled UV lasers, including miniaturization, low-cost mass production, mechanical and environmental stability, high speed modulation, wavelength tunability and high efficiency. Diode lasers with these advantages would not just replace existing lasers in existing applications such as lithography, industrial marking, (bio)chemical and environmental monitoring and scientific instrumentation, but would also enable a host of new portable applications in these diverse fields.

Technical Description

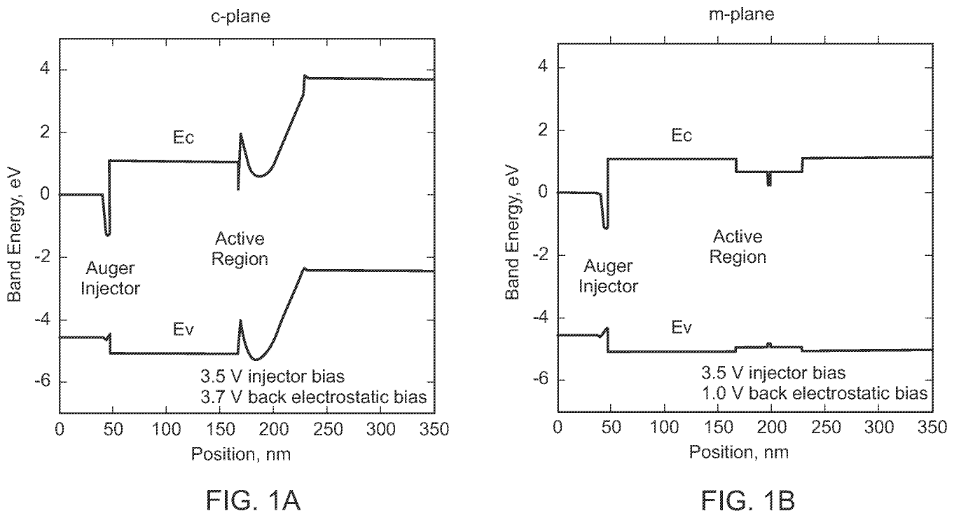

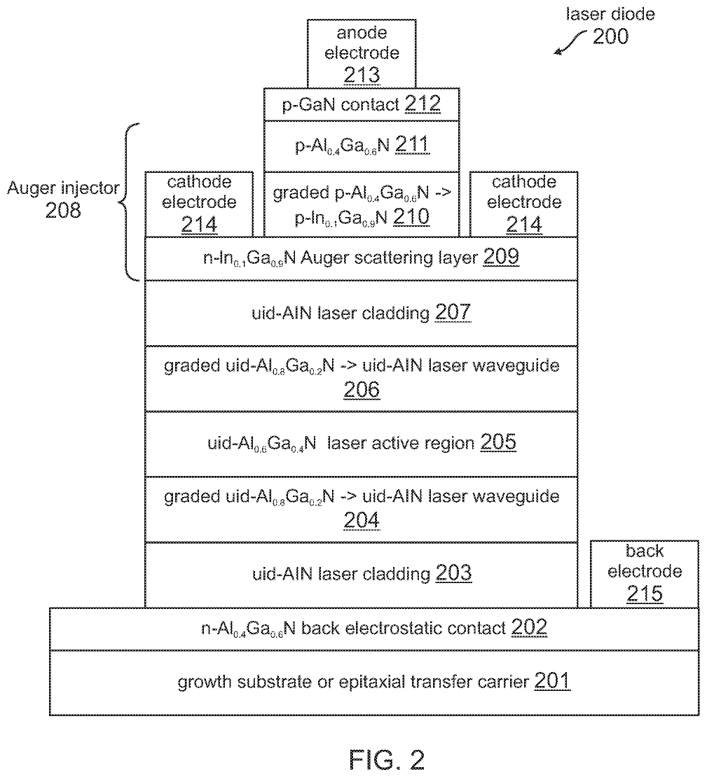

The invention is best understood by reference to the band diagrams shown in FIG. 1A, as well as the accompanying physical structure shown schematically in FIG. 2.

FIG. 1A is a band diagram under bias of a c-plane embodiment of a Group-III nitride laser diode of the present invention, showing the band energy of both the conduction band edge Ec and the valence band edge Ev, as well as the positions of an Auger injector and an active region relative to a growth substrate. In this example, there is a 3.5 V injector bias and a 3.7 V back electrostatic bias.

FIG. 2 is a schematic view of the c-plane embodiment of the laser diode 200 of FIG. 1A, wherein the laser diode 200 is grown epitaxially on a growth substrate 201 or epitaxial transfer carrier, which may comprise a polar (0001) AlN substrate 201, or on an AlN template itself grown lattice-mismatched upon a substrate 201 such as sapphire or SiC. An n-type AlGaN back electrostatic contact layer 202 may be included on or above the substrate 201, as described in more detail below. The laser diode 200 further comprises an AlN lower cladding layer 203, an optional step or graded AlGaN waveguide layer 204 of band gap smaller than the cladding layer 203, an AlGaN active region 205 comprising one or more AlGaN layers of band gap smaller than the waveguide layer 204 separated by AlGaN layers of band gap larger than the active region 205 layers, another step or graded AlGaN waveguide layer 206 of composition similar to the first waveguide layer 204, and another AlN cladding layer 207. None of these layers 203, 204, 205, 206, 207 require doping for electrical conductivity.

Upon the last mentioned AlN cladding layer 207 is disposed a structure 208, hereafter referred to as an Auger injector 208, which is an electrically-driven p-n junction comprising an n-type InGaN Auger scattering layer 209, typically with indium mole fraction between 0-30%, followed by a compositionally-graded p-type AlGaInN Auger carrier generation layer 210, followed by a p-type AlGaN layer 211, typically with aluminum mole fraction between 0-40%.

These layers 209, 210, 211 may optionally be preceded and/or followed by one or more AlGaN layers or superlattices (not shown) that serve to reflect high energy (e.g., hot) Auger carriers traveling toward a p-GaN contact 212 back toward the active region 205 or suppress electron reflection at an interface between the injector 208 and cladding 207 of Auger carriers traveling toward the active region 205. Such “multiple quantum barrier” blocking structures have been demonstrated in InGaN-based visible diode lasers [7], and multiple quantum barrier anti-reflection structures may be formed by altering the layer compositions and thicknesses, analogous to optical high-reflection Bragg or Rugate reflectors and anti-reflection multilayer coatings.

Any of these layers may be graded in composition and/or doping to better control carrier generation and injection into the wider bandgap laser structure.

In operation, electron and hole currents are injected into the relatively low band gap Auger injector 208 p-n junction from the top and lateral anode and cathode electrodes 213, 214. Carriers are confined by the adjacent AlN structures 206, 207 and AlGaN structure 211, resulting in carrier densities well above 1×10¹⁹ cm⁻³, densities known to be high enough to efficiently produce energetic electrons and holes via interband Auger recombination [6]. These Auger scattered carriers possess enough kinetic energy to surmount the potential barrier at the interface to the AlN structures 206, 207, and so be injected into the AlN structures 206, 207, where they drift or diffuse toward the AlGaN active region 205 where they recombine to produce Spontaneous emission or produce laser gain.

Both Auger-scattered electrons and holes have been observed to escape from quantum wells in which they were generated, to be captured and radiatively recombine in adjacent quantum wells of different composition with higher recombination energies [4]. Auger carriers with momentum in the wrong direction may be at least partially redirected by the quasi-electric fields associated with compositional grading or by Bragg reflection by an optional blocking layer or layers or a superlattice. Bragg reflection is elastic so those carriers will retain enough energy to continue into the AlN cladding 207.

Unlike conventional design, no electrical contact is needed to the wide band gap cladding layers 203, 207 or waveguide layers 204, 206. The non-injecting contact layer 202 and accompanying back electrode 215 might be included below the first AlN cladding layer 203, such as through a conducting SiC substrate or AlGaN layer of moderate composition, to electrostatically control band tilt in the wide band gap structure due to, for example, piezoelectric fields from polar heterointerfaces.

The optical mode propagating in the plane of the structure may be confined laterally by a rib structure and transversally by the Group-III nitride waveguide layers 204, 206 and cladding layers 203, 207, as in conventional design, or transversally by dielectric layers formed on each side of the structure after removal of the growth substrate, as demonstrated in near infrared lasers [8] and proposed by [9].

At least one current component, preferably the electron current, must be injected laterally from one or both sides of the rib waveguide, i.e., via n-electrodes 214, through a very thin conducting layer 209. Calculations indicate that current spreading in an n-type GaN layer 209 only 2 nm thick will introduce an additional 10 Ohms to the series resistance of a 2 μm wide laser rib, which is undesirable but tolerable.

Auger scattering in a highly excited InGaN layer 209 may be quite efficient, consuming as much as 50% of the injected current in green-emitting InGaN lasers at threshold. It is thought that carrier localization in nanostructures such as self-assembled InGaN quantum dots or disks further increases the ratio of Auger recombination to radiative recombination [10]. It is also known that Auger scattering may arise due to defects or interfaces in AlGaN layers 211 or superlattices [11] through trap-assisted Auger recombination (TAAR). TAAR was observed to have very high efficiency in p-n junctions with single AlGaN barriers [11], but also to saturate at high injection currents, so multiple AlGaN barriers can be used to generate enough hot electron current through TAAR.

If lasing and clamping of the carrier density in the Auger injector 208 is suppressed, for example, by using facet coatings that are antireflective at the band gap of the injector 208, and with conventional carrier leakage from the injector 208 suppressed by the very wide band gap AlGaN layers 211 or AlN layers 206, 207 adjacent to the injector 208, the carrier density may be pushed high enough to reach an Auger scattering fraction of more than 90%. With effective carrier blocking and anti-reflection structures as described above, most of these Auger-scattered carriers will ultimately be injected into the laser active region 205.

### Preferred Embodiment

The preferred embodiment is shown in FIG. 2 and described above. Additionally, the preferred substrate 201 is bulk single crystal polar c-plane AlN, commercially available although quite expensive. The Auger generation layers comprise highly n doped and p doped InGaN layers 209, 210, each only a few nanometers thick and of indium mole fraction less than 10%. High reflectivity and low reflectivity facet coatings (not shown) are applied to the laser facets, fabricated in suitably non-absorbing materials such as Al₂O₃ and AlF or SiO₂. Access to the very thin lateral contact layer 209 may be made by precise wet or dry etching, or by ion implantation or diffusion from the uppermost surface, or by interrupting the crystal growth after the lateral contact layer 209 is grown, masking the eventual lateral contact area with a suitable material, finishing the epitaxial structure by selective area growth, and then removing the mask for access to the contact area.

### First Alternative Embodiment

In a first alternative embodiment, the laser structure is grown upon a single crystal bulk nonpolar AlN substrate, commercially available although quite expensive compared to a polar AlN substrate. On this orientation, uniform or graded composition AlGaN separate confinement heterostructure waveguides may be formed without concern for band bending due to bulk polarization gradients, allowing the laser active region to be positioned at the peak of the optical mode for higher confinement factor.

FIG. 1B is a band diagram under bias of an m-plane embodiment of a Group-III nitride laser diode according to the present invention, showing the band energy of both the conduction band edge Ec and the valence band edge Ev, as well as the positions of an Auger injector and an active region. In this example, there is a 3.5 V injector bias and a 1.0 V back electrostatic bias.

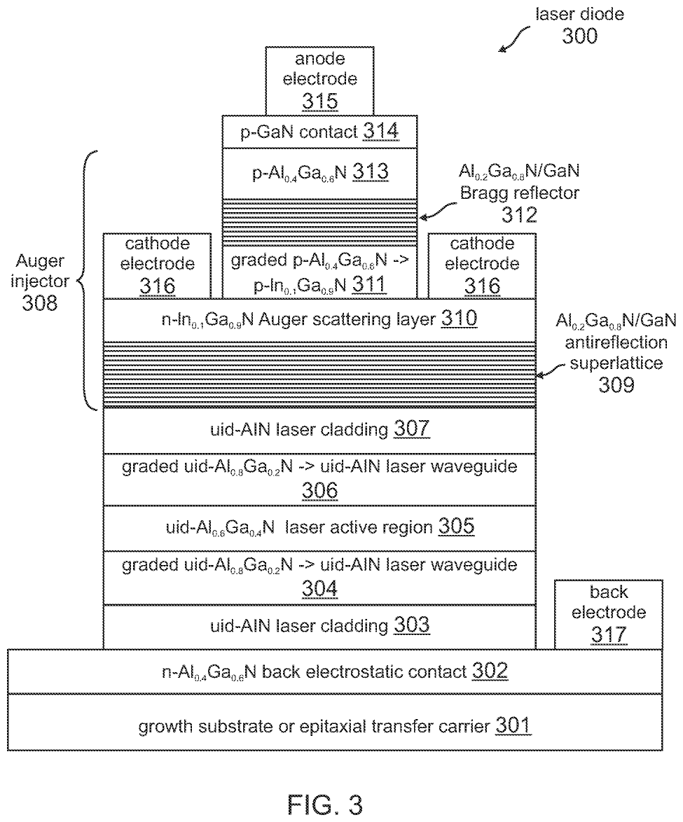

FIG. 3 is a schematic view of the m-plane embodiment of the laser diode of FIG. 1B, wherein the laser diode 300 incorporates a Bragg reflector and antireflection superlattice to improve Auger injection into the laser active region. In this embodiment, the laser diode 300 is grown upon a growth substrate 301 or epitaxial transfer carrier, for example, a substrate 301 comprised of single crystal AlN template films grown upon lattice-mismatched bulk GaN, SiC or sapphire substrates, with or without known defect-blocking techniques such as substrate patterning before template growth, lateral epitaxial overgrowth, or strain relaxation by compliant underlayers.

Like FIG. 2, the laser 300 further comprises an AlN lower cladding layer 303, an optional step or graded AlGaN waveguide layer 304 of band gap smaller than the cladding layer 303, an AlGaN active region 305 comprising one or more AlGaN layers of band gap smaller than the waveguide layer 304 separated by AlGaN layers of band gap larger than the active region 305 layers, another step or graded AlGaN waveguide layer 306 of composition similar to the first waveguide layer 304, and another AlN cladding layer 307. None of these layers 303, 304, 305, 306, 307 require doping for electrical conductivity.

Upon the last mentioned AlN cladding layer 307 is disposed an Auger injector 308, including an AlGaN/GaN antireflection superlattice 309, an n-type InGaN scattering layer 310, a p-type InGaN Auger carrier generation layer 311, an AlGaN/GaN Bragg reflector 312, followed by a p-type AlGaN layer 313. The AlGaN/GaN Bragg reflector 312 reflects high energy Auger carriers traveling toward the p-contact 314 back toward the active region 305, and the AlGaN/GaN antireflection superlattice 309 suppresses electron reflection of Auger carriers traveling toward the active region 205 at the interface between the Auger injector 308 and the cladding layer 307.

As in FIG. 2, electron and hole currents are injected into the relatively low band gap Auger injector 308 p-n junction from the top and lateral anode and cathode electrodes 315, 316. The non-injecting contact layer 302 and accompanying back electrode 317 might be included below the first AlN cladding layer 303 to electrostatically control band tilt in the wide band gap structure.

### Second Alternative Embodiment

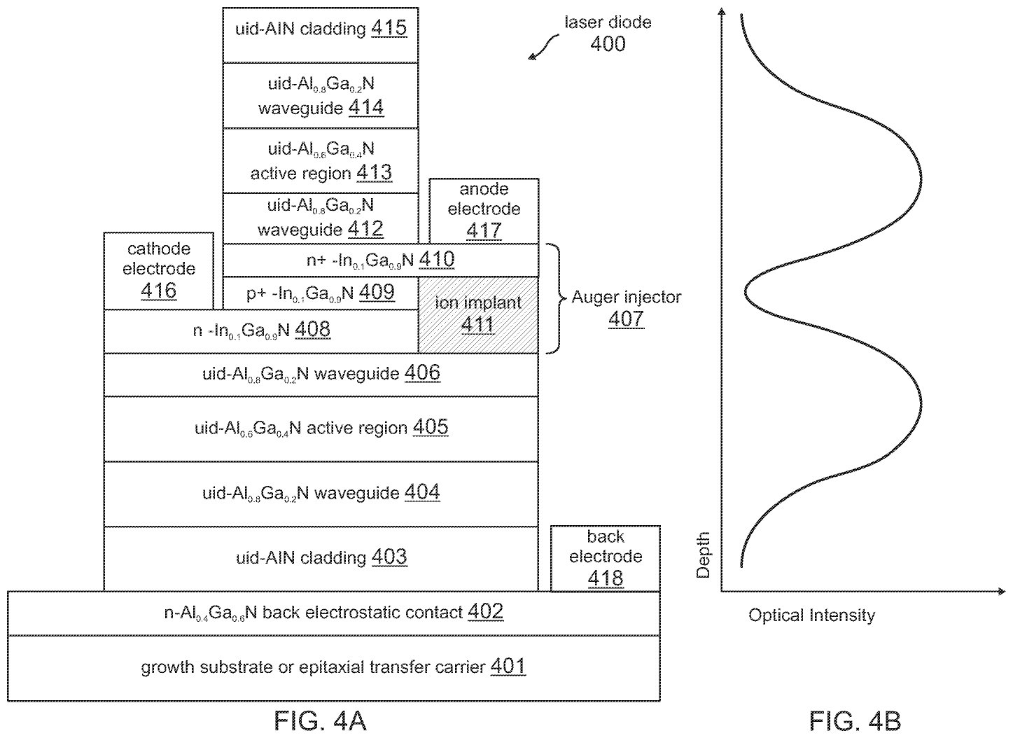

In a second alternative embodiment, no Auger carrier-reflecting structure is included but a second UV-emitting active region is added on the opposite side of the Auger injector from the first UV emitting active region, to collect excited carriers on both sides of the Auger injector. FIG. 4A illustrates a laser diode 400 according to this embodiment, comprising a growth substrate 401, an n-AlGaN back electrostatic contact 402, a uid-AlN cladding layer 403, a uid-AlGaN waveguide layer 404, a uid-AlGaN active region 405, a uid-AlGaN waveguide layer 406, an Auger injector 407 comprising an n-InGaN cathode contact layer 408 and a tunnel junction comprising a p+-InGaN hole injector 409 and an n+ InGaN anode contact layer 410. An ion implanted region 411 directs electron current laterally. The anode contact layer 410 is followed by a uid-AlGaN waveguide layer 412, a second uid-AlGaN active region 413, a uid-AlGaN waveguide layer 414 and a uid AlN cladding layer 415. A cathode electrode 416 is disposed upon the cathode layer 408, and an anode electrode 417 is disposed upon the anode layer 410. A back electrode 418 is disposed upon the back electrostatic contact layer 402. In this embodiment, the laser waveguide may be designed to operate on the usual fundamental transverse mode, or on a higher order mode of odd symmetry such that the Auger injector, which is absorbing at the intended operating wavelength, resides at a null of the optical field intensity, whereas the two active regions reside at peaks of the optical field intensity, as shown in FIG. 4B.

### Other Alternative Embodiments

The present invention provides a number of other alternative embodiments:

In another alternative embodiment, the InGaN and AlGaN layers of the Auger injector structures are of graded composition and/or doping.

In another alternative embodiment, the Auger generation layers comprise nanoscale islands or disks embedded in wider bandgap wetting layers, such as In_{0.1}Ga_{0.9}N quantum dots embedded in a GaN p-n junction. Typical dimensions of the islands are 2 nm high and 2-20 nm wide, embedded in highly doped n-type and p-type layers each 2 nm thick.

In another alternative embodiment, the layers of the Auger injector structure comprise AlGaInN single layer, multiple AlGaInN layers or superlattices embedded between GaN injecting contacts to enhance interface and trap-assisted Auger recombination.

In another alternative embodiment, a p-type AlGaN layer is disposed between the injector structure and the adjacent cladding layer, with an optional unintentionally doped layer between the injector structure and the p-type AlGaN, to provide additional Auger scattering via trap-assisted Auger recombination.

In another alternative embodiment, single or multiple semiconductor layers or a semiconductor superlattice Bragg or Rugate reflector is disposed between the injector and the p-type contact layer to redirect Auger-scattered carriers traveling toward the anode contact back toward the laser active region. The thickness and composition of the Auger carrier reflector layers may be designed such that the effective absorption edge is at higher energy than the intended operating photon energy [12].

In another alternative embodiment, single or multiple semiconductor layers or a semiconductor superlattice is disposed between the Auger injector and the adjacent cladding layer, designed to suppress quantum mechanical reflection of high energy carriers at the interface between the injector and the cladding, just the opposite function provided by an Auger carrier Bragg reflector.

In another alternative embodiment, the laser waveguide layers are of uniform composition rather than graded, forming a conventional separate confinement heterostructure.

In another alternative embodiment, the laser waveguide layers are disposed asymmetrically about the laser active region.

In another alternative embodiment, optical Bragg gratings are fabricated within, on top of, or alongside the laser rib to augment or control the optical resonator.

In another alternative embodiment, metallic or optical Bragg reflectors are fabricated bounding the epitaxial structure to form a vertical cavity surface emitting laser or resonant cavity LED.

In another alternative embodiment, the facets or gratings are omitted, and the device serves as a light emitting diode (LED), still benefiting from Auger scattering for carrier injection into wide band gap carrier transport and active region layers.

In another alternative embodiment, multiple devices are arranged in a monolithic array, emitting independently as lasers or LEDs or coherently coupled emitting as a single laser.

Novel and Inventive Features

The present invention provides a number of novel and inventive features:

A Group-III nitride light emitting device that utilizes scattering of hot carriers generated by Auger recombination from an externally electrically-driven, relatively narrow band gap carrier generation region into an internally electrically-driven relatively wide band gap carrier recombination region.

Use for generation of incoherent light (an LED) or coherent light (a laser).

Use of bulk Group-III nitride substrates of polar, semipolar or nonpolar orientation, or Group-III nitride template layers grown on substrates other than Group-III nitride materials, such as bulk crystalline sapphire or silicon carbide.

Incorporation of graded composition layers to redirect the hot carriers scattered in the wrong direction toward the active region.

Incorporation of a carrier-reflecting structure to redirect the scattered hot carriers toward the active region, optionally designed as a superlattice with an optical absorption edge of higher energy than the intended operating photon energy.

Incorporation of a carrier anti-reflection structure to improve transmission of scattered hot carriers toward the active region, optionally designed as a superlattice with an optical absorption edge of higher energy than the intended operating photon energy.

Incorporation of a p-type AlGaN layer to provide additional carriers via trap-assisted Auger recombination.

Incorporation of a second active region within a wide band gap transport layer on the side of the Auger carrier generation structure opposite from the first active region.

Incorporation of Group-III nitride waveguide core and cladding layers to provide transverse optical confinement of a lasing optical mode, using step-index or graded-index layers, and designed to operate on the fundamental even-symmetry transverse mode with a single active region or a higher order odd-symmetry transverse mode with a null at the Auger carrier generation structure in the case of multiple active regions disposed on either side of the Auger carrier generation structure.

Incorporation of Group-III nitride waveguide layers disposed asymmetrically about the laser active region.

Incorporation of rib, ridge, or buried ridge structures to provide lateral confinement of a lasing optical mode.

Incorporation of at least one lateral contact structure to inject at least one carrier type into the electrically driven carrier generation region.

Incorporation of a third electrostatic contact to control band tilt or bending in the wider bandgap layers.

Incorporation of defects or multiple interfaces such as superlattices that enhance Auger scattering.

Incorporation of low-dimensional Group-III nitride structures for hot carrier generation, including quantum wells, or quantum dots or disks.

Incorporation of laser facet coatings, antireflective at the wavelength of light unintentionally generated in the Auger injector region, and reflective or antireflective at the intended operating wavelength.

Incorporation of optical Bragg gratings upon, within, or adjacent to the laser waveguide to enhance or control the optical resonator properties of the waveguide.

Incorporation of metallic and/or optical Bragg reflectors to form a vertical cavity resonator.

Monolithic arrays of Auger-pumped LEDs, or lasers operating independently or coherently coupled.

A method to provide access to the lateral contact layer or layers for deposition of anode and/or cathode electrodes, based on selective area growth.

Fabrication Process

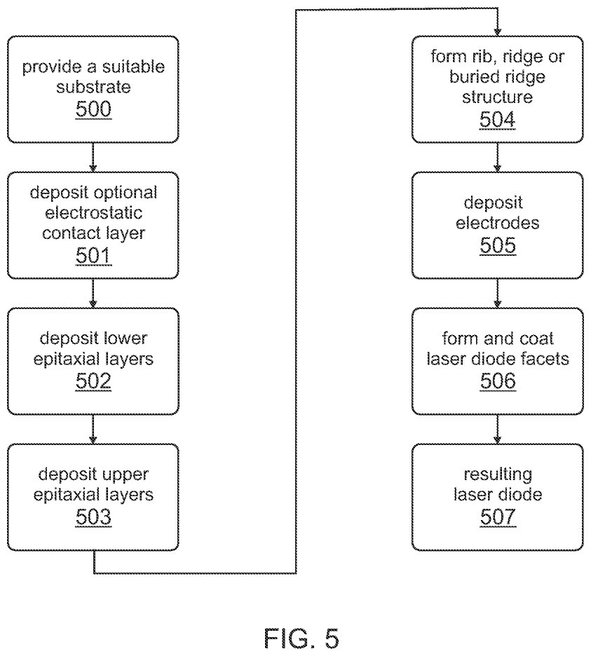

FIG. 5 is a flow chart showing the process steps for fabricating and operating a III-nitride based laser diode according to the present invention, namely, a Group-III nitride light emitting device that utilizes scattering of hot carriers generated by Auger recombination from an externally electrically-driven, relatively narrow band gap carrier generation region into a relatively wide band gap carrier recombination region, such that the relatively wide band gap carrier recombination region of the Group-III nitride light emitting device is internally electrically-injected by the hot carriers generated in the externally electrically-injected relatively narrow band gap carrier generation region, in order to generate coherent or incoherent light. Specifically, these steps may be used to fabricate the (Al,Ga,In)N epitaxial structures forming the laser diode as shown in FIGS. 2, 3 and 4A. The method may comprise the following steps.

Block 500 represents the step of providing a suitable substrate for the Group-III nitride light emitting device.

The substrate may be comprised of a bulk Group-III nitride substrate of polar, semipolar or nonpolar orientation, or of Group-III nitride template layers grown on a substrate other than a Group-III nitride substrate.

Block 501 represents the optional step of depositing an optional n-type AlGaN back electrostatic contact layer on the substrate.

Block 502 represents the step of forming a portion of the laser diode's epitaxial structure, optionally by selective area growth, for example, by depositing an AlN lower cladding layer, an optional step or graded AlGaN waveguide layer, an AlGaN active region, another optional step or graded AlGaN waveguide layer, another AlN cladding layer, an optional AlGaN/GaN antireflection superlattice, and an n-InGaN Auger scattering layer.

The AlGaN active region comprises the relatively wide band gap carrier recombination region, while the optional step or graded AlGaN waveguide layers comprise graded composition layers, namely, graded uid-Al_{0.8}Ga_{0.2}N→uid-AlN, incorporated into the device to redirect the hot carriers into the relatively wide band gap carrier recombination region.

The Group-III nitride waveguide and cladding layers are incorporated into the device to provide transverse optical confinement of a lasing optical mode, using step-index or graded-index layers.

The Group-III nitride waveguide and cladding layers may operate on a fundamental even-symmetry transverse mode with a single active region or a higher order odd-symmetry transverse mode with a null at the carrier generation region when multiple active regions are disposed on either side of the carrier generation region.

The Group-III nitride waveguide layers may also be disposed asymmetrically about the active region.

The device may incorporate optical Bragg gratings upon, within, or adjacent to, the laser waveguide to enhance or control optical resonator properties of the laser waveguide.

The device may also incorporate metallic and/or optical Bragg reflectors to form a vertical cavity resonator.

Block 503 represents the step of forming a remainder of the laser diode's epitaxial structure, optionally by selective area growth, for example by depositing an optional AlGaN/GaN antireflection superlattice, a compositionally graded p-type AlGaInN Auger carrier generation layer, an optional AlGaN/GaN Bragg reflector, a p-AlGaN layer and a p-GaN contact layer.

The p-type AlGaInN Auger carrier generation layer comprises the externally electrically-driven, relatively narrow band gap carrier generation region, which generates the hot carriers via trap-assisted Auger recombination.

The device may incorporate low-dimensional Group-III nitride structures in the carrier generation region for generating the hot carriers, including quantum wells, quantum dots or quantum disks.

The p-type AlGaInN Auger carrier generation layer may comprise graded composition layers, namely, graded p-Al_{0.4}Ga_{0.6}N→p-In_{0.1}Ga_{0.9}N, to redirect the hot carriers into the relatively wide band gap carrier recombination region.

The device may incorporate defects or multiple interfaces such as superlattices that enhance the scattering of the hot carriers.

The AlGaN/GaN Bragg reflector comprises a carrier-reflecting structure incorporated into the device to redirect the scattered hot carriers toward the active region, and the carrier-reflecting structure is one or more semiconductor layers or a semiconductor superlattice.

The AlGaN/GaN antireflection superlattice is a carrier anti-reflection structure incorporated into the device to transmit the scattered hot carriers toward the active region, and the carrier anti-reflection structure is one or more semiconductor layers or a semiconductor superlattice.

The carrier-reflecting or the carrier anti-reflection structures comprise semiconducting layers having a band gap and thickness such that an effective optical absorption edge is of an energy greater than an intended operating photon energy.

The device may incorporate a second active region within a wide band gap transport layer on a side of the carrier generation region opposite from a first active region.

Block 504 represents the step of forming a rib, ridge or buried ridge structure for the device to provide lateral confinement of a lasing optical mode.

Block 505 represents the step of depositing anode, cathode and back electrostatic electrodes onto their respective contact layers.

The device incorporates at least one lateral contact structure, e.g., the cathode electrodes, to inject at least one carrier type into the carrier generation region.

The device provides access to one or more lateral contact layers for deposition of anode and/or cathode electrodes, based on selective area growth.

The device may also incorporate an electrostatic contact, e.g., the back electrode, to control band tilt or bending in wider bandgap layers.

Block 506 represents the step of forming and coating the laser facets.

The device may incorporate laser facet coatings that are antireflective at a wavelength of light unintentionally generated in the Auger injector, and reflective or antireflective at an intended operating wavelength.

Block 507 represents the end result of the method, a device such as a Group-III nitride light emitting device as shown in FIGS. 1A, 1B, 2, 3, 4A and 4B, wherein the device may be operated by applying an electrical bias to utilize scattering of hot carriers generated by Auger recombination in an externally electrically-driven, relatively narrow band gap carrier generation region into a relatively wide band gap carrier recombination region, such that the relatively wide band gap carrier recombination region of the Group-III nitride light emitting device is internally electrically-injected by the hot carriers generated in the externally electrically-injected relatively narrow band gap carrier generation region.

The device may also comprise monolithic arrays of Auger-pumped light-emitting diodes or laser diodes operating independently or coherently coupled.

### REFERENCES

The following publications and applications are incorporated by reference herein:

[1] Z. Zhang, Appl. Phys. Express, 12, 124003 (2019).

[2] T. Wunderer, Appl. Phys. Express, 4, 092101 (2011)

[3] K. J. Vampola, Appl. Phys. Lett. 94, 061116 (2009).

[4] M. Binder, Appl. Phys. Lett. 103, 071108 (2013).

[5] A. Nirschl, J. Appl. Phys. 118, 033103 (2015).

[6] J. Iveland, Phys. Rev. Lett., 110, 177406 (2013).

[7] S.-N. Lee, Phys. Stat. Sol. 3, 2215 (2006).

[8] T. Shindo, Optics Express 19, 1884 (2011).

[9] U.S. Provisional Patent Application Ser. No. 62/121,981, filed Feb. 27, 2015, by Daniel A. Cohen et al., entitled “GROUP-III NITRIDE LASER WITH DUAL TRANSPARENT CONDUCTING OXIDE CLADDING LAYERS”, attorneys' docket number 30794.0585USP1(UC 2015-336-1).

[10] M. Shahmohammadi, Phys. Rev. B 95, 125314 (2017).

[11] D. Myers, Phys. Rev. B, 100, 125303 (2019).

[12] B. Cheng, Appl. Phys. Lett., 102, 231106 (2013).

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A device, comprising:
a Group-III nitride light emitting device that utilizes scattering of hot carriers generated by Auger recombination in an externally electrically-driven, relatively narrow band gap carrier generation region into a relatively wide band gap carrier recombination region, such that the relatively wide band gap carrier recombination region of the Group-III nitride light emitting device is internally electrically injected by the hot carriers generated in the externally electrically-driven relatively narrow band gap carrier generation region.

2. The device of claim 1, wherein the Group-III nitride light emitting device generates incoherent or coherent light.

3. The device of claim 1, wherein the Group-III nitride light emitting device is comprised of a bulk Group-III nitride substrate of polar, semipolar or nonpolar orientation, or of Group-III nitride template layers grown on a substrate other than a Group-III nitride substrate.

4. The device of claim 1, wherein the Group-III nitride light emitting device incorporates graded composition layers to redirect the scattered hot carriers into the relatively wide gap carrier recombination region.

5. The device of claim 1, wherein the Group-III nitride light emitting device incorporates a carrier-reflecting structure to redirect the scattered hot carriers toward an active region, and the carrier-reflecting structure is one or more semiconductor layers or a semiconductor superlattice.

6. The device of claim 1, wherein the Group-III nitride light emitting device incorporates a carrier anti-reflection structure to transmit the scattered hot carriers toward an active region, and the carrier anti-reflecting structure is one or more semiconductor layers or a semiconductor superlattice.

7. The device of claim 1, 5 or 6, wherein the carrier reflecting or anti-reflecting structures comprise semiconducting layers of band gap and thickness such that the effective optical absorption edge is of an energy greater than an intended operating photon energy.

8. The device of claim 1, wherein the Group-III nitride light emitting device incorporates a p-type AlGaN layer to generate hot carriers via trap-assisted Auger recombination.

9. The device of claim 1, wherein the Group-III nitride light emitting device incorporates a second active region on a side of the carrier generation region opposite from a first active region.

10. The device of claim 1, wherein the Group-III nitride light emitting device incorporates Group-III nitride waveguide and cladding layers to provide transverse optical confinement of a lasing optical mode, using step-index or graded-index layers, wherein the Group-III nitride waveguide and cladding layers operate on a fundamental even-symmetry transverse mode with a single active region or a higher order odd-symmetry transverse mode with a null at the carrier generation region when multiple active regions are disposed on either side of the carrier generation region.

11. The device of claim 1, wherein the Group-III nitride light emitting device incorporates Group-III nitride waveguide layers disposed asymmetrically about an active region.

12. The device of claim 1, wherein the Group-III nitride light emitting device incorporates rib, ridge, or buried ridge structures to provide lateral confinement of a lasing optical mode.

13. The device of claim 1, wherein the Group-III nitride light emitting device incorporates at least one lateral contact structure to inject at least one carrier type into the carrier generation region.

14. The device of claim 1, wherein the Group-III nitride light emitting device incorporates an electrostatic contact to control band tilt or bending in wider bandgap layers.

15. The device of claim 1, wherein the Group-III nitride light emitting device incorporates defects or multiple interfaces such as superlattices that enhance the scattering of the hot carriers.

16. The device of claim 1, wherein the Group-III nitride light emitting device incorporates low-dimensional Group-III nitride structures for generating the hot carriers, including quantum wells, quantum dots or quantum disks.

17. The device of claim 1, wherein the Group-III nitride light emitting device incorporates laser facet coatings that are antireflective at a wavelength of light unintentionally generated in an Auger injector, and reflective or antireflective at an intended operating wavelength.

18. The device of claim 1, wherein the Group-III nitride light emitting device incorporates optical Bragg gratings upon, within, or adjacent to, a laser waveguide to enhance or control optical resonator properties of the laser waveguide.

19. The device of claim 1, wherein the Group-III nitride light emitting device incorporates metallic and/or optical Bragg reflectors to form a vertical cavity resonator.

20. The device of claim 1, wherein the Group-III nitride light emitting device further comprises monolithic arrays of Auger-pumped light-emitting diodes or laser diodes operating independently or coherently coupled.

21. The device of claim 1, wherein the Group-III nitride light emitting device provides access to one or more lateral contact layers for deposition of anode and/or cathode electrodes, based on selective area growth.

22. A method, comprising:
fabricating a Group-III nitride light emitting device that utilizes scattering of hot carriers generated by Auger recombination in an externally electrically driven, relatively narrow band gap carrier generation region into a relatively wide band gap carrier recombination region, such that the relatively wide band gap carrier recombination region of the Group-III nitride light emitting device is internally electrically injected by the hot carriers generated in the externally electrically-driven relatively narrow band gap carrier generation region.

23. A method, comprising:
operating a Group-III nitride light emitting device that utilizes scattering of hot carriers generated by Auger recombination from an externally electrically driven, relatively narrow gap band carrier generation region into a relatively wide band gap carrier recombination region, such that the Group-III nitride light emitting device is internally electrically injected by the hot carriers generated in the externally electrically-driven relatively narrow band gap carrier generation region.
